(19) United States
(12) Patent Application Publication
(10) Pub. No.: US 2024/0312839 A1
(43) Pub. Date: Sep. 19, 2024

(54) FULLY ALIGNED VIA TO SINGLE DAMASCENE UPPER TRENCH

(71) Applicant: International Business Machines Corporation, Armonk, NY (US)

(72) Inventors: Chanro Park, Clifton Park, NY (US); Koichi Motoyama, Clifton Park, NY (US); Yann Mignot, Slingerlands, NY (US)

(21) Appl. No.: 18/122,680

(22) Filed: Mar. 16, 2023

(51) Int. Cl. H01L 21/768; H01L 23/535

(52) U.S. Cl. CPC H01L 21/76897; H01L 21/76805; H01L 21/76843; H01L 21/76895; H01L 23/535

(57) ABSTRACT

A semiconductor interconnect structure and formation thereof. The semiconductor interconnect structure includes a lower level via that is fully aligned to an upper level metal line. The lower level via is elongated along a lower level metal line direction and partially recessed.

### BACKGROUND

The present disclosure generally relates to fabrication methods and structures for semiconductor devices, and more specifically, to lower level vias that are fully aligned to upper level metal lines when transitioning between lower level vias formed by subtractive patterning to metal lines formed by a single damascene process.

An integrated circuit (IC) device may be formed with millions of transistors and other circuit elements that are fabricated on a single silicon crystal substrate (wafer). For the IC device to be functional, multi-level or multi-layered interconnection schemes such as, for example, metal wiring formed by single damascene processes, dual damascene processes, subtractive patterning (i.e., subtractive etch processes), and combinations thereof, are fabricated in the back-end-of-the-line (BEOL) of the device to connect the circuit elements distributed in the front-end-of-the-line (FEOL) of the device.

### SUMMARY

According to one embodiment of the present invention, a semiconductor interconnect structure is provided. The semiconductor interconnect structure includes a lower level via that is fully aligned to an upper level metal line. The lower level via is elongated along a lower level metal line direction and is partially recessed.

According to another embodiment of the present invention, a semiconductor interconnect structure is provided. The semiconductor interconnect structure includes a contact via that is fully aligned to an upper level metal line. The contact via is elongated along a gate direction and is partially recessed.

According to another embodiment of the present invention, a method of forming a semiconductor interconnect structure is provided. The method includes forming a via on top of a lower level metal line using subtractive patterning. The via is elongated along the lower level metal line direction. The method further includes forming a first interlayer dielectric layer, such that a top surface of the first interlayer dielectric layer is coplanar with a top surface of the via. The method further includes forming an upper level dummy line on top of the via, such that a first portion of the via adjacent to a first side of the upper level dummy line and a second portion of the via adjacent to a second side of the upper level dummy line remain exposed. The method further includes partially recessing the first and second portions of the via to form a first recessed portion and a second recessed portion. The method further includes forming a second interlayer dielectric layer on top of the first interlayer dielectric layer and within the first and second recessed portions, such that a top surface of the second interlayer dielectric layer is coplanar with a top surface of the dummy line. The method further includes replacing the upper level dummy line with an upper level metal line using a single damascene process. The via is fully aligned to the lower level metal line and the upper level metal line.

### BRIEF DESCRIPTION OF THE SEVERAL VIEWS OF THE DRAWINGS

FIG. 1A illustrates a top view of an initial semiconductor structure, generally designated 100, in accordance with at least one embodiment of the present invention.

FIG. 1B illustrates a cross-sectional view of semiconductor structure 100 taken along line 1B, in accordance with at least one embodiment of the present invention.

FIG. 1C illustrates a cross-sectional view of semiconductor structure 100 taken along line 1C, in accordance with at least one embodiment of the present invention.

FIG. 1D illustrates a cross-sectional view of semiconductor structure 100 taken along line 1D, in accordance with at least one embodiment of the present invention.

FIG. 2A illustrates a top view of semiconductor structure 100 after performing subsequent processing steps, generally designated 200, in accordance with at least one embodiment of the present invention.

FIG. 2B illustrates a cross-sectional view of semiconductor structure 200 taken along line 2B, in accordance with at least one embodiment of the present invention.

FIG. 2C illustrates a cross-sectional view of semiconductor structure 200 taken along line 2C, in accordance with at least one embodiment of the present invention.

FIG. 2D illustrates a cross-sectional view of semiconductor structure 200 taken along line 2D, in accordance with at least one embodiment of the present invention.

FIG. 3A illustrates a top view of semiconductor structure 200 after performing subsequent processing steps, generally designated 300, in accordance with at least one embodiment of the present invention.

FIG. 3B illustrates a cross-sectional view of semiconductor structure 300 taken along line 3B, in accordance with at least one embodiment of the present invention.

FIG. 3C illustrates a cross-sectional view of semiconductor structure 300 taken along line 3C, in accordance with at least one embodiment of the present invention.

FIG. 3D illustrates a cross-sectional view of semiconductor structure 300 taken along line 3D, in accordance with at least one embodiment of the present invention.

FIG. 4A illustrates a top view of semiconductor structure 300 after performing subsequent processing steps, generally designated 400, in accordance with at least one embodiment of the present invention.

FIG. 4B illustrates a cross-sectional view of semiconductor structure 400 taken along line 4B, in accordance with at least one embodiment of the present invention.

FIG. 4C illustrates a cross-sectional view of semiconductor structure 400 taken along line 4C, in accordance with at least one embodiment of the present invention.

FIG. 4D illustrates a cross-sectional view of semiconductor structure 400 taken along line 4D, in accordance with at least one embodiment of the present invention.

FIG. 5A illustrates a top view of semiconductor structure 400 after performing subsequent processing steps, generally designated 500, in accordance with at least one embodiment of the present invention.

FIG. 5B illustrates a cross-sectional view of semiconductor structure 500 taken along line 5B, in accordance with at least one embodiment of the present invention.

FIG. 5C illustrates a cross-sectional view of semiconductor structure 500 taken along line 5C, in accordance with at least one embodiment of the present invention.

FIG. 5D illustrates a cross-sectional view of semiconductor structure 500 taken along line 5D, in accordance with at least one embodiment of the present invention.

FIG. 6A illustrates a top view of semiconductor structure 500 after performing subsequent processing steps, generally designated 600, in accordance with at least one embodiment of the present invention.

FIG. 6B illustrates a cross-sectional view of semiconductor structure 600 taken along line 6B, in accordance with at least one embodiment of the present invention.

FIG. 6C illustrates a cross-sectional view of semiconductor structure 600 taken along line 6C, in accordance with at least one embodiment of the present invention.

FIG. 6D illustrates a cross-sectional view of semiconductor structure 600 taken along line 6D, in accordance with at least one embodiment of the present invention.

FIG. 7A illustrates a top view of semiconductor structure 600 after performing subsequent processing steps, generally designated 700, in accordance with at least one embodiment of the present invention.

FIG. 7B illustrates a cross-sectional view of semiconductor structure 700 taken along line 7B, in accordance with at least one embodiment of the present invention.

FIG. 7C illustrates a cross-sectional view of semiconductor structure 700 taken along line 7C, in accordance with at least one embodiment of the present invention.

FIG. 7D illustrates a cross-sectional view of semiconductor structure 700 taken along line 7D, in accordance with at least one embodiment of the present invention.

FIG. 8 is flowchart diagram depicting a method 800 of fabricating a semiconductor interconnect structure corresponding to the semiconductor structures described with reference to FIGS. 1A-1D . . . 7A-7D, in accordance with at least one embodiment of the present invention.

FIG. 9 is flowchart diagram depicting a method 900 of fabricating a semiconductor interconnect structure corresponding to the semiconductor structures described with reference to FIGS. 1A-1D . . . 7A-7D, in accordance with at least one embodiment of the present invention.

### DETAILED DESCRIPTION

For tight pitch interconnect fabrication, subtractive patterning of a metal or metal alloy is generally preferred over the use of conventional single or dual copper (Cu) damascene processes due to various structural and performance advantages. For example, by employing subtractive patterning rather than a single or dual damascene process, via alignment and interconnect overlap issues between a via and the underlying/overlying interconnects may be greatly reduced, if not eliminated. However, while subtractive patterning has its advantages, single damascene and/or dual damascene Cu processes are typically still preferred for instances when the interconnect pitch is relaxed (e.g., greater than 30 nm) due to certain cost and performance benefits. Thus, a mixture of subtractive patterning and damascene processes is often preferred.

Typically, the pitch between interconnects of the same interconnect level increases as the interconnect level increases. Accordingly, there may come a point in the fabrication of the back-end-of-the-line (BEOL) structure at which the transition from a lower level via formed by subtractive patterning to an upper level metal line formed by a single damascene process is required due to a change in interconnect pitch between two interconnect levels. In other words, a transition from a via formed on top of an underlying interconnect structure using subtractive patterning to an overlying interconnect formed on top of the via using a single copper (Cu) damascene process.

Embodiments of the present invention recognize that this transition may result in via misalignment and interconnect overlap issues between a lower level via formed using subtractive pattering and an overlying upper level interconnect formed using a single damascene process. For example, an interconnect that does not fully land on the contact area of the underlying via will result in increased contact resistance between the interconnect and via. This contact resistance increases as the amount of overlap between the interconnect and the contact area of the underlying via decreases. In order to reduce via misalignment and interconnect overlap issues, the contact area of the via may be increased by elongating the via along the direction of the underlying interconnect. By elongating the via to provide a larger contact area for the overlying interconnect, the overlap between the via and interconnect is increased, thereby also decreasing the contact resistance. However, embodiments of the present invention recognize that increasing the contact area of the via does not come without a tradeoff. By elongating the via to increase the contact area for an overlying interconnect, the distance between the contact area of the via and neighboring upper level interconnects is decreased, resulting in an increased risk of shorting and reliability concerns.

Embodiments of the present invention provide for improved interconnect structures and methods of forming the same when transitioning from a lower level via formed by subtractive patterning to an upper level metal line formed by a damascene process that reduces and/or eliminates contact resistance between the lower level via and the upper level metal line, while also reducing and/or eliminating shorting risks and reliability concerns between the lower level via and neighboring upper level metal lines. According to embodiments of the present invention, an initial lower level via that is elongated along the direction of a lower level metal line is formed on top of the lower level metal line using subtractive metal patterning. The initial lower level via is formed such that a length of the via running along the lower level metal line direction is longer than the width of the final upper level metal line to be formed on top of the lower level via. This is to ensure that a bottom surface of the final upper level metal line to be formed fully overlaps or contacts the lower level via. A dummy line, acting as a placeholder for the final upper level metal line, is formed on top of the initial elongated via, such that portions of the via remain exposed after forming the dummy line. The exposed portions of the lower level via are then recessed, such that the contact area of the lower level via is now fully aligned with the dummy line (i.e., the dummy line completely overlaps the top surface of the via without any overhang). The dummy line is then removed to form a trench that is fully aligned with the contact area of the via. Lastly, metallization of the trench is performed to form a metal line that is fully aligned with the contact area of the underlying via without any overlap issues. Furthermore, by recessing the portions of the lower level via that are not in contact with the upper level metal line, any shorting risks and reliability concerns between the lower level via and neighboring upper level metal lines are avoided.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, micromachining, microetching, wet and/or dry etching processes, plasma etching processes, or any of the known etching processes in which material is removed.

As used herein, the terms “metal level,” “metal layer,” “interconnect level,” and “interconnect layer” may be used interchangeably and may refer to one of a plurality of metal wiring levels in the BEOL of an integrated circuit (IC).

As used herein, the term “source/drain contact” may refer to a contact that extends from below a transistor to make electrical contact to a source region and/or drain region of the transistor.

As used herein, the term “contact via” may refer to a lowest level via of the BEOL of an integrated circuit (IC) used to make an electrical connection between a source/drain contact and a metal line in a lowest metal level of the BEOL.

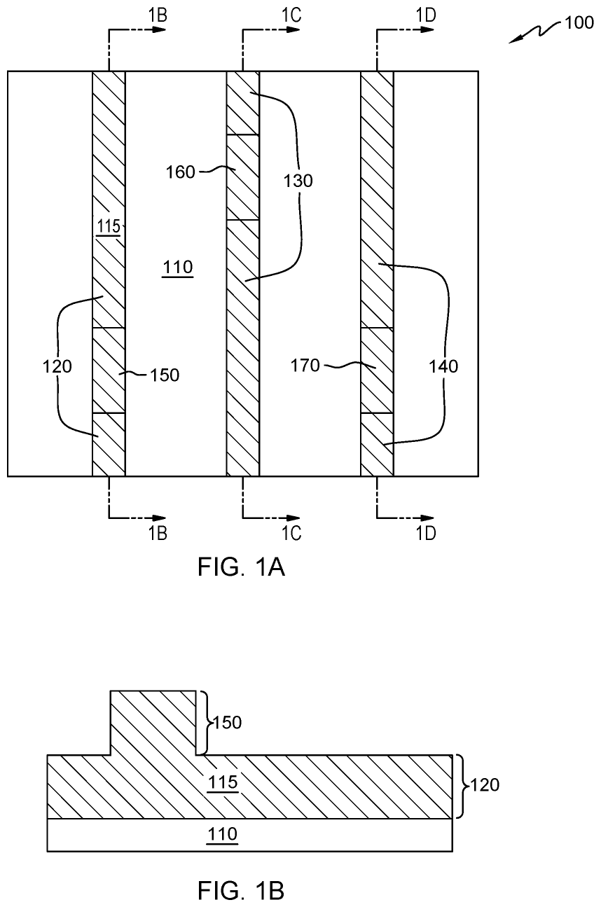

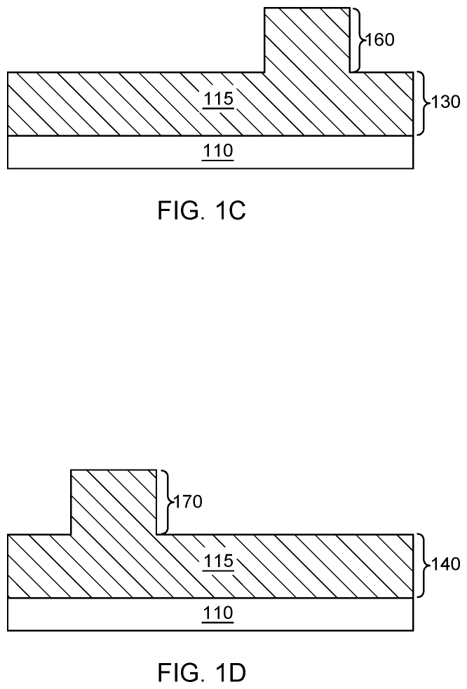

The present invention will now be described in detail with reference to the Figures. FIGS. 1A . . . 1D-7A . . . 7D include various views depicting illustrative steps of a method for manufacturing semiconductor interconnect structures and the resulting semiconductor interconnect structures according to select embodiments of the present invention. One having ordinary skill in the art will appreciate that there are many options available for the formation of the structures described herein and that the following discussion does not limit embodiments to only the techniques described herein.

FIGS. 1A-1D illustrate a top view and corresponding cross-sectional views of an initial semiconductor structure 100, in accordance with at least one embodiment of the present invention. Referring to the top view of FIG. 1A and the cross-sectional views of FIGS. 1B-1D taken along corresponding lines 1B, 1C, 1D, elements 120, 130, 140 are formed on a substrate 110, and elements 150, 160, 170 are formed on top of elements 120, 130, 140.

In some embodiments, substrate 110 may be part of a front-end-of-the-line (FEOL) structure. A FEOL structure is typically present beneath the lowest level of the multilayered interconnect structure and includes a semiconductor substrate having one or more semiconductor devices such as, for example, transistors, capacitors, resistors, and etc. located thereon. In other embodiments, substrate 110 may include one or more interconnect levels of a multilayered interconnect structure, such as a back-end-of-the-line (BEOL) structure. A BEOL structure is typically where the individual semiconductor devices in the FEOL structure are interconnected with one another. In such embodiments, each interconnect level (i.e., metal level) may include one or more electrically conductive structures embedded in an interconnect dielectric material. For example, the one or more interconnect levels of a multilayer interconnect structure may be formed from any generally known semiconductor materials, such as silicon, gallium arsenide, or germanium.

In some embodiments, and as depicted in FIGS. 1A-1D, substrate 110 is a bulk semiconductor wafer, such as a bulk silicon (Si), bulk germanium (Ge), bulk silicon germanium (SiGe) and/or bulk III-V semiconductor wafer. Alternatively, in other embodiments, substrate 110 is a semiconductor-on-insulator (SOI) wafer. A SOI wafter includes a SOI layer separated from a substrate by a buried insulator. When the buried insulator is an oxide, it is referred to herein as a buried oxide or BOX. The SOI layer can include any suitable semiconductor, such as Si, Ge, SiGe, and/or a III-V semiconductor.

In some embodiments, and as depicted in FIGS. 1A-1D, elements 120, 130, 140 are representative of a first set of metal lines of a first metal wiring level and elements 150, 160, 170 are representative of a first set of vias. In other embodiments, elements 120, 130, 140 are representative of a first set of source/drain contacts and elements 150, 160, 170 are representative of a first set of contact vias. In these embodiments, contact via 150, 160, 170 are elongated along the gate direction (not depicted).

For discussion purposes only, and unless otherwise specified herein, elements 120, 130, 140 shall be referred to as metal lines 120, 130, 140 and elements 150, 160, 170 shall be referred to as vias 150, 160, 170. However, the illustrated operations of FIGS. 1A-1D . . . 7A-7D will be understood to be similarly applicable to elements 120, 130, 140 and elements 150, 160, 170 being representative of source/drain contacts and contact via, respectively. Moreover, any operations, features, benefits, etc. that are described with respect to a particular fabrication sequence corresponding to elements 120, 130, 140 being representative of metal lines and elements 150, 160, 170 being representative of vias will be understood to be similarly applicable to elements 120, 130, 140 being representative of source/drain contacts and elements 150, 160, 170 being representative of contact vias, unless explicitly noted.

In assembly of semiconductor structure 100, a conductive metal layer 115 is formed by depositing a conductive metal material (e.g., via physical vapor deposition (PVD), atomic layer deposition (ALD), chemical vapor deposition (CVD), plasma enhanced CVD (PECVD), or any other suitable deposition techniques) onto the top surface of substrate 110. In an embodiment, the conductive metal material may be a metal or metal alloy including, but not limited to, aluminum (Al), ruthenium (Ru), rhodium (Rh), iridium (Ir), tungsten (W), molybdenum (Mo), nickel (Ni), or an alloy thereof.

Next, one or more subtractive etch processes are performed to pattern conductive metal layer 115 to form metal lines 120, 130, 140 and vias 150, 160, 170 on top thereof. For example, a hard mask layer (not depicted) is formed by depositing a hard mask material (e.g., silicon nitride, titanium nitride, tantalum nitride, or any suitable metal-containing material) onto the top surface of conductive metal layer 115. The hard mask layer can be formed utilizing a deposition process including, but not limited to, PVD, CVD, PECVD, ALD, or sputtering.

A photoresist material (not depicted) is then deposited onto the surface of the hard mask layer. The photoresist material can be applied by any suitable techniques, including, but not limited to, coating or spin-on techniques. A photomask (not depicted) patterned with shapes defining metal lines 120, 130, 140 and vias 150, 160, 170 to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the hard mask layer. Dry etch techniques (for example, an anisotropic etch process, such as reactive ion etch) may be employed to selectively remove portions of the hard mask layer to form the patterned hard mask. After formation of patterned hard mask, the photoresist material may be stripped from the patterned hard mask by ashing or other suitable processes. The resulting structure may be subjected to a wet clean.

During patterning of conductive metal layer 115 using the patterned hard mask, the physically exposed portions of conductive metal layer 115 are removed by an anisotropic etching process such as, for example, reactive ion etching (RIE), ion beam etching (IBE), chemical wet etching, or a combination of IBE and chemical wet etching. The etch removes the exposed portions of conductive metal layer 115 that are not protected by the patterned hard mask to form metal lines 120, 130, 140 and vias 150, 160, 170. It should be appreciated that unlike single or dual damascene processes, in which vias are formed below metal lines, vias 150, 160, 170 are formed on top of metal lines 120, 130, 140 as a result of performing subtractive patterning of conductive metal layer 115. Similarly, in embodiments where elements 120, 130, 140 are representative of source/drain contacts, and elements 150, 160, 170 are representative of contact vias, contact vias 150, 160, 170 are formed on top of source/drain contacts 120, 130, 140 as a result of performing the one or more subtractive etch processes to pattern conductive metal layer 115.

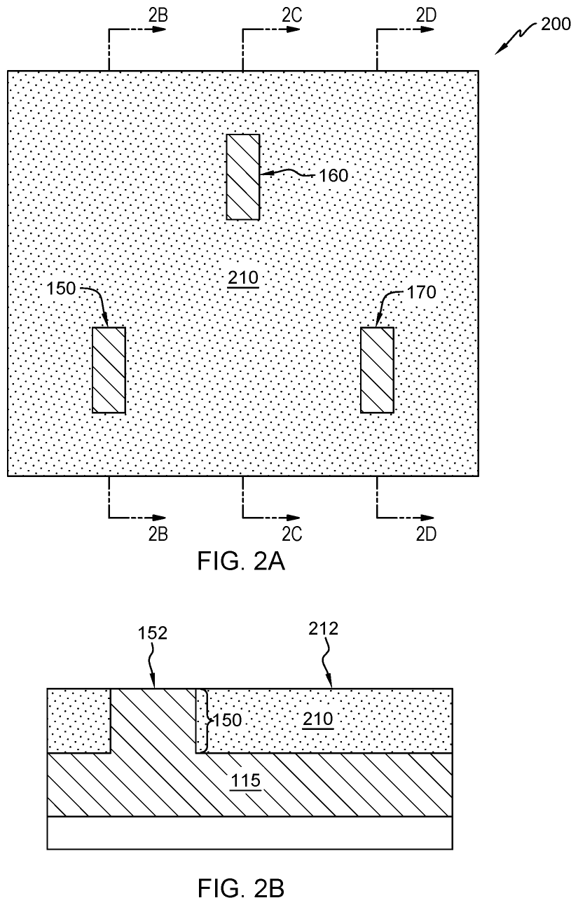

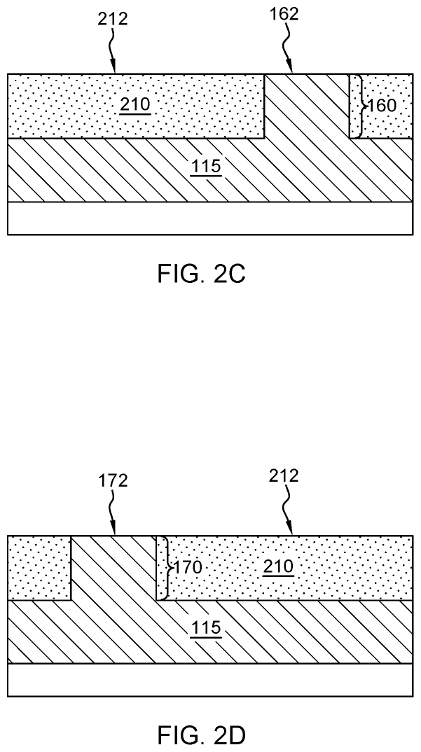

FIGS. 2A-2D illustrate a top view and corresponding cross-sectional views of semiconductor structure 100 depicted in FIGS. 1A-1D after performing subsequent processing steps, generally designated 200, in accordance with at least one embodiment of the present invention. In assembly of semiconductor structure 200, and referring to the top view of FIG. 2A and the cross-sectional views of FIGS. 2B-2D taken along corresponding lines 2B, 2C, 2D, an interlayer dielectric (ILD) material is conformally deposited onto the patterned conductive metal layer 115 to form ILD layer 210.

ILD layer 210 may be composed of an inorganic dielectric material or an organic dielectric material. In some embodiments, ILD layer 210 may be porous. In other embodiments, ILD layer 210 may be non-porous. In some embodiments, ILD layer 210 may have a dielectric constant (all dielectric constants mentioned herein are measured relative to a vacuum, unless otherwise stated) that is about 4.0 or less. In an embodiment, ILD layer 210 may have a dielectric constant of 2.8 or less. These dielectrics having a dielectric constant of 2.8 or less generally have a lower parasitic cross talk as compared to dielectric materials whose dielectric constant is greater than 4.0. Examples of suitable dielectric materials that may be employed as ILD layer 210 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

A planarization process such as, for example, chemical mechanical planarization or polishing (CMP) and/or grinding, may subsequently be performed to remove portions of ILD layer 210 present above top surfaces 152, 162, 172 of vias 150, 160, 170. The planarization stops when top surface 212 of ILD layer 210 is substantially coplanar with top surfaces 152, 162, 172 of vias 150, 160, 170.

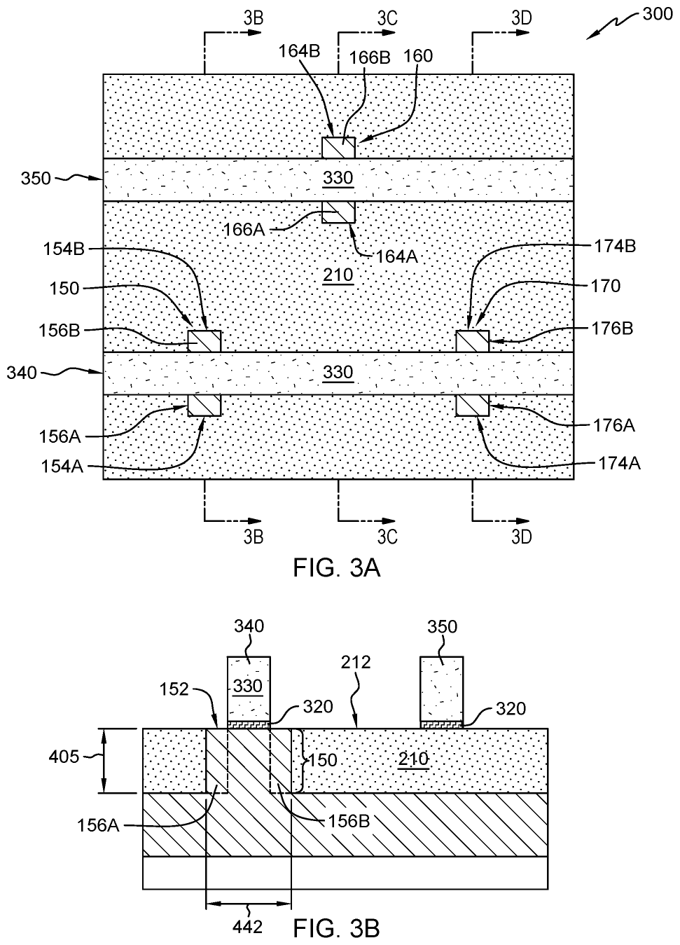

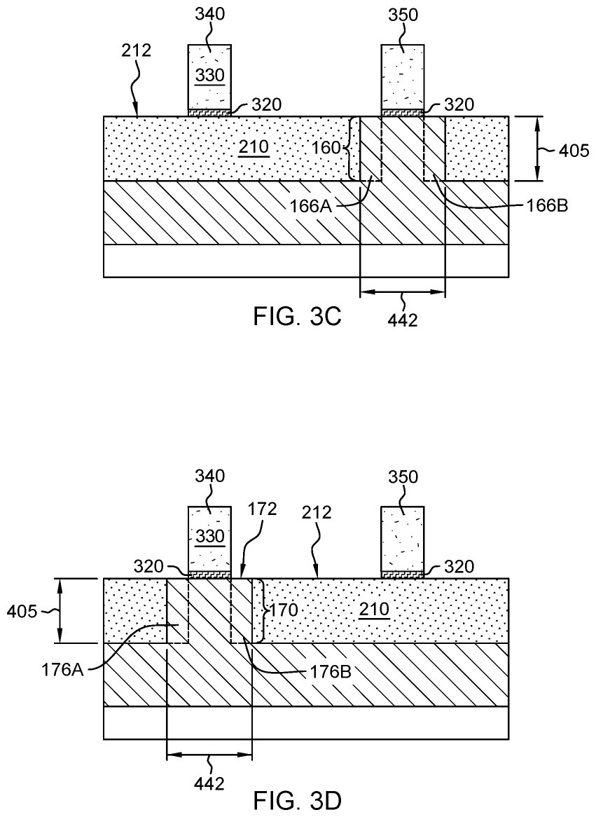

FIGS. 3A-3D illustrate a top view and corresponding cross-sectional views of semiconductor structure 200 depicted in FIGS. 2A-2D after performing subsequent processing steps, generally designated 300, in accordance with at least one embodiment of the present invention. In assembly of semiconductor structure 300, and referring to the top view of FIG. 3A and the cross-sectional views of FIGS. 3B-3D taken along corresponding lines 3B, 3C, 3D, dummy lines 340, 350 are formed on top of respective portions of top surfaces 152, 162, 172 of vias 150, 160, 170 and respective portions of top surface 212 of ILD layer 210. As used herein, top surfaces 152, 162, 172 of vias 150, 160, 170 may generally be referred to as “contact areas,” and shall generally mean the available area of a top surface of a lower level via by which an upper level dummy line and/or metal line may be in contact with.

In some embodiments, dummy lines 340, 350 are formed by optionally conformally depositing an etch stop material onto the top surface of semiconductor structure 200 (depicted in FIGS. 2A-2D) to form an etch stop layer 320, depositing a dummy material onto the optional etch stop layer 320 to form a dummy layer 330, and patterning the optional etch stop layer 320 and dummy layer 330 to form dummy lines 340, 350. In some embodiments, etch stop layer 320 may be composed of a sacrificial material, including, but not limited to, tantalum (Ta), tantalum nitride (TaN), titanium (T), and titanium nitride (TiN). In some embodiments, dummy layer 330 may be composed of a sacrificial material, including, but not limited to silicon (Si), silicon dioxide (SiO2), and silicon nitride (SIN). The dummy layer 330 may be planarized to a desired level.

Etch stop layer 320 and dummy layer 330 may be formed by depositing the etch stop material and the dummy material using known techniques including, but not limited to, chemical vapor deposition (CVD), plasma enhanced chemical vapor deposition (PECVD), atomic layer deposition (ALD), physical vapor deposition (PVD), sputtering, chemical solution deposition or plating. The thickness of etch stop layer 320 may vary depending on the deposition process used, as well as the material employed. In some embodiments, etch stop layer may have a thickness from 1 nm to 5 nm. However, other thicknesses that are less than 1 nm, or greater than 5 nm can also be employed in embodiments of the present invention.

Dummy lines 340, 350 may be formed by patterning the optional etch stop layer 320 and dummy layer 330 using the same processes and materials as described above with reference to FIGS. 1A-1D. For example, a patterned hard mask may be formed on top of dummy layer 330. The resulting patterned hard mask, which acts as an etch mask, is formed such that the portions of the underlying etch stop layer 320 and dummy layer 330 corresponding to dummy lines 340, 350 to be formed are protected by the patterned hard mask, while the remaining portions of the underlying etch stop layer 320 and dummy layer 330 are left exposed. During patterning of etch stop layer 320 and dummy layer 330 using the patterned hard mask, the physically exposed portions of etch stop layer 320 and dummy layer 330 are removed by an anisotropic etching process such as, for example, reactive ion etching (RIE), ion beam etching (IBE), chemical wet etching, or a combination of IBE and chemical wet etching to form dummy lines 340, 350.

Dummy lines 340, 350 are respectively arranged on top of vias 150, 160, 170 such that no portion of the bottom surfaces 342, 352 of dummy lines 340, 350 overhang or extend beyond sides 154A, 154B of via 150, sides 164A, 164B of via 160, and sides 174A, 174B of via 170. This is evinced by the fact that portions 156A, 156B of via 150, portions 166A, 166B of via 160, and portions 176A, 176B of via 170 remain exposed after forming dummy lines 340, 350.

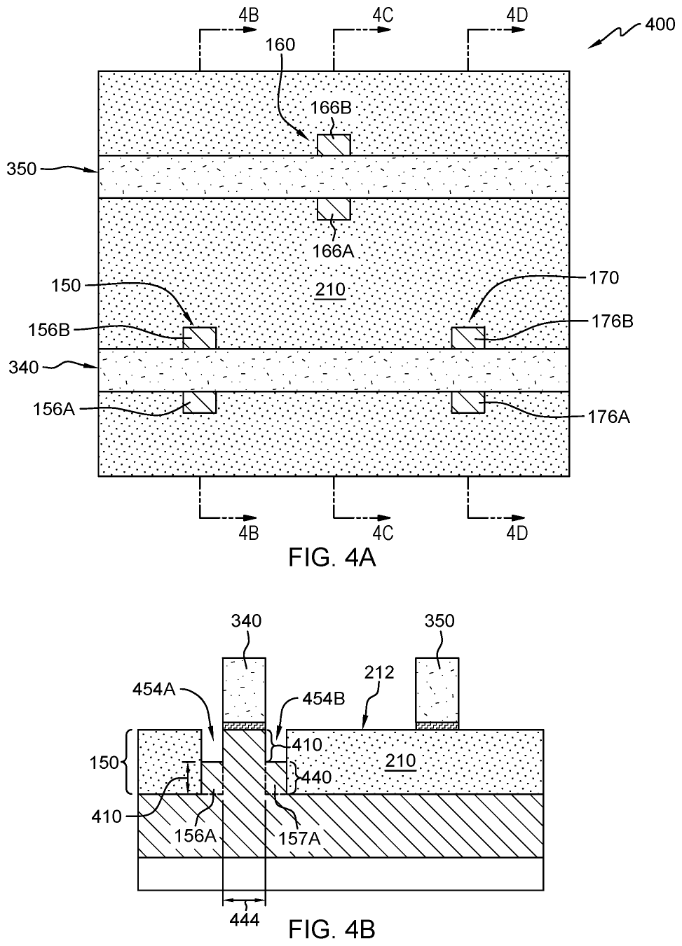

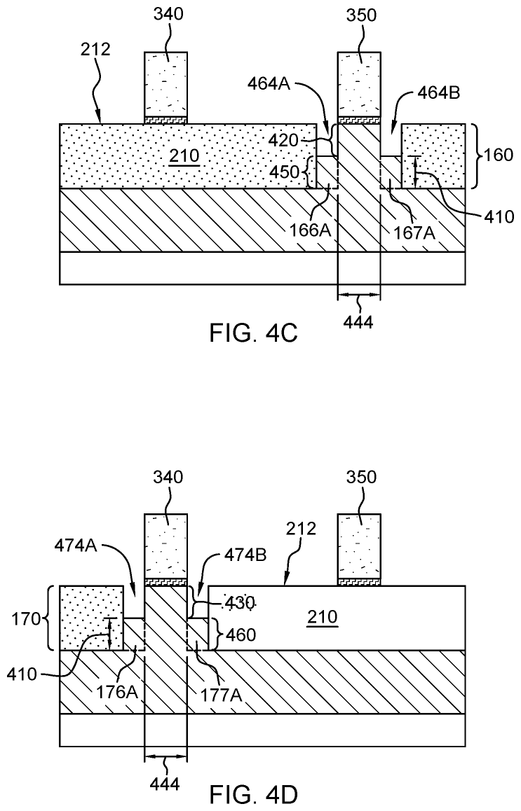

FIGS. 4A-4D illustrate a top view and corresponding cross-sectional views of semiconductor structure 300 depicted in FIGS. 3A-3D after performing subsequent processing steps, generally designated 400, in accordance with at least one embodiment of the present invention. In assembly of semiconductor structure 400, and referring to the top view of FIG. 4A and the cross-sectional views of FIGS. 4B-4D taken along corresponding lines 4B, 4C, 4D, portions 156A, 156B, 166A, 166B, 176A, 176B of vias 150, 160, 170 are partially recessed below top surface 212 of ILD layer 210 by an anisotropic etching process such as, for example, reactive ion etching (RIE), ion beam etching (IBE), chemical wet etching, or a combination of IBE and chemical wet etching.

As a result of the partial recess of vias 150, 160, 170, portions 156A, 156B of via 150, portions 166A, 166B of via 160, and portions 176A, 176B of via 170 have been reduced from a first height 405 (depicted in FIGS. 3B-3D) to a second height 410. As a further result of the partial recess of vias 150, 160, 170, top portions 410, 420, 430 of vias 150, 160, and 170 have been reduced from a first width 442 (depicted in FIGS. 3B-3D) to a second width 444, such that top portions 410, 420, 430 of vias 150, 160, 170 are now narrower than bottom portions 440, 450, 460 of vias 150, 160, 170. It should be appreciated that by reducing the width of top portions 410, 420, 430 of vias 150, 160, and 170 from width 442 to width 444, the width 444 of the contact areas of vias 150, 160, 170 has also been reduced to that of the width 446 of dummy lines 340, 350. In other words, vias 150, 160, 170 are now fully aligned with dummy lines 340, 350. Accordingly, dummy lines 340, 350 completely overlap the contact areas of vias 150, 160, 170 without any overhang.

The recessing of portions 154A, 154B, 164A, 164B, 174A, 174B of vias 150, 160, 170 further results in the formation of cavities 454A, 454B, 464A, 464B, 474A, 474B. The depth of cavities 454A, 454B, 464A, 464B, 474A, 474B can be controlled by a timed etching process and may vary based on the given application. In some embodiments, the depth of cavities 454A, 454B, 464A, 464B, 474A, 474B is between 5 to 10 nm in depth. However, other depths that are less than 5 nm, or greater than 10 nm can also be employed in embodiments of the present invention. For example, the depth of cavities 454A, 454B, 464A, 464B, 474A, 474B may be selected such that the width 444 and the height 410 of top portions 410, 420, 420 of vias 150, 160, 170 are equal.

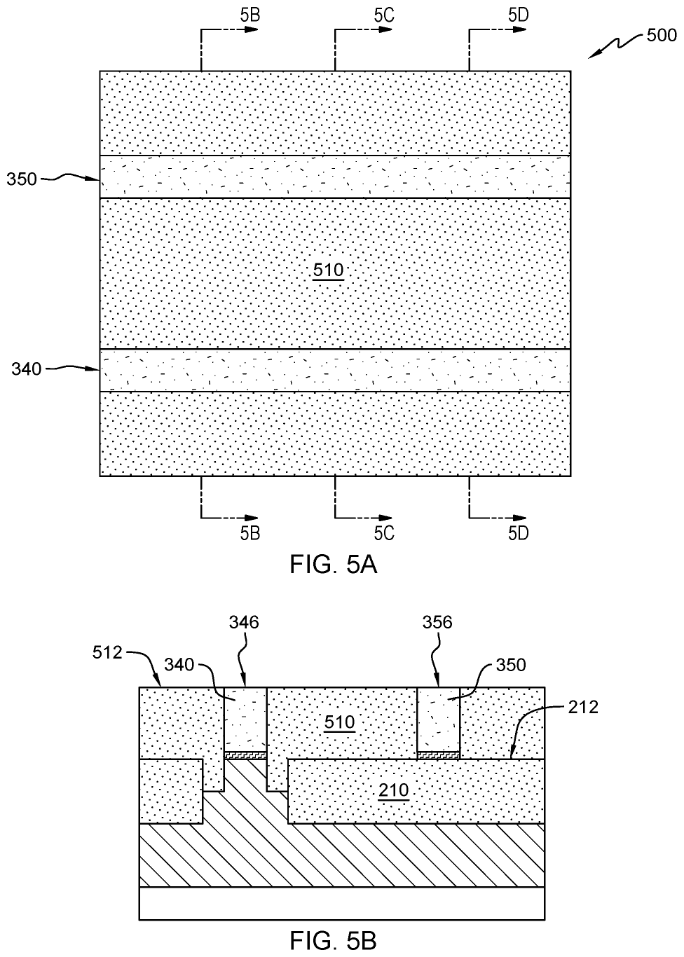

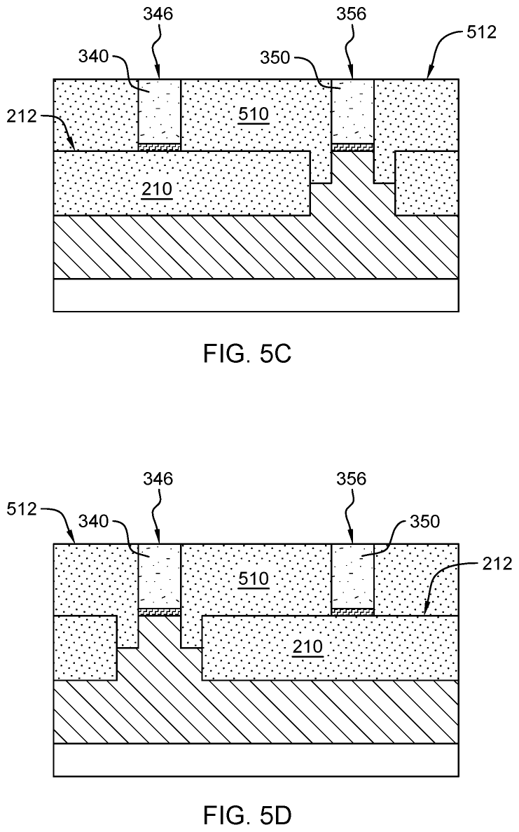

FIGS. 5A-5D illustrate a plan view and corresponding cross-sectional views of semiconductor structure 400 depicted in FIGS. 4A-4D after performing subsequent processing steps, generally designated 500, in accordance with at least one embodiment of the present invention. In assembly of semiconductor structure 500, and referring to the top view of FIG. 5A and the cross-sectional views of FIGS. 5B-5D taken along corresponding lines 5B, 5C, 5D, an interlayer dielectric (ILD) material is deposited (e.g., via atomic layer deposition, chemical vapor deposition, plating, electroplating, or any other suitable deposition techniques) onto semiconductor structure 400 (depicted in FIGS. 4A-4D) to form an interlayer dielectric (ILD) layer 510. ILD layer 510 may be composed of any of the materials previously mentioned with respect to the material composition of ILD layer 210. In some embodiments, ILD layer 510 and ILD layer 210 are formed from the same material(s). In other embodiments, ILD layer 510 and ILD layer 210 are formed from different materials.

ILD layer 510 is formed within and filling cavities 454A, 454B, 464A, 464B, 474A, 474B (depicted in FIGS. 4B-4D), as well as on top of the exposed portions of top surface 212 of ILD layer 210 until ILD layer 510 is at least substantially coplanar with top surfaces 346, 356 of dummy lines 340, 350. A planarization process such as, for example, chemical mechanical planarization or polishing (CMP) and/or grinding, may subsequently be performed to remove portions of ILD layer 510 present above top surfaces 346, 356 of dummy lines 340, 350. The planarization may stop when top surface 512 of ILD layer 510 is substantially coplanar with top surfaces 346, 356 of dummy lines 340, 350.

In some embodiments, prior to forming ILD layer 510, the exposed portions of ILD layer 210 (i.e., those portions that are not located underneath dummy lines 340, 350) are optionally recessed by an anisotropic etching process such as, for example, reactive ion etching (RIE), ion beam etching (IBE), chemical wet etching, or a combination of IBE and chemical wet etching. The depth of the recessed portions of ILD layer 210 can be controlled using a timed etching process. In some embodiments, the exposed portions of ILD layer 210 are recessed down to at least the bottom surfaces of cavities 454A, 454B, 464A, 464B, 474A, 474B (depicted in FIGS. 4B-4D). In doing so, any potential plasma damage resulting from partially etching portions 156A, 156B, 166A, 166B, 176A, 176B of vias 150, 160, 170 may be removed prior to forming ILD layer 510.

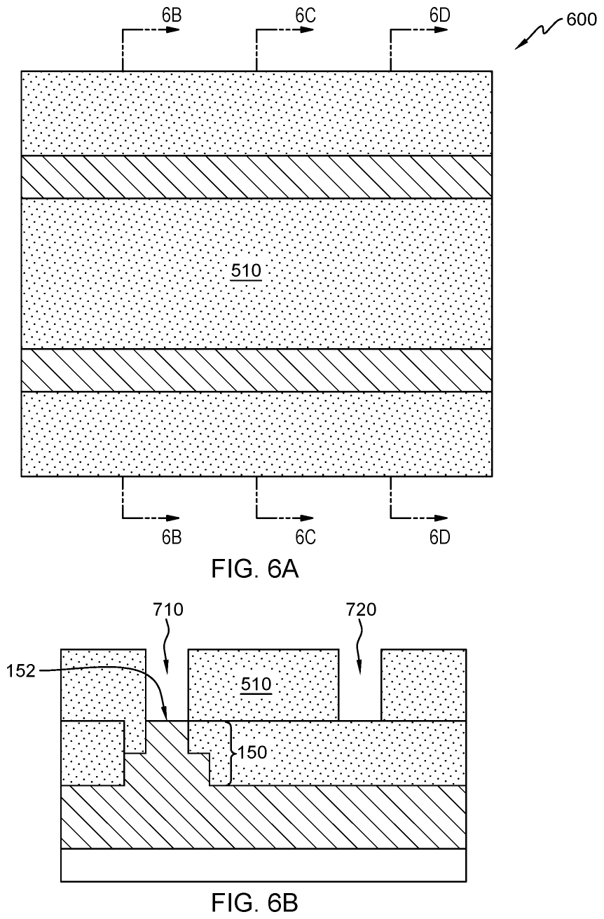

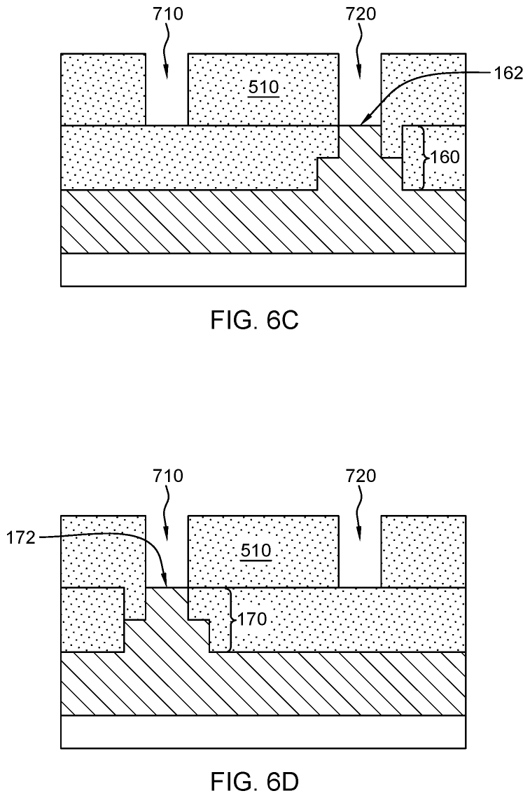

FIGS. 6A-6D illustrate a plan view and corresponding cross-sectional views of semiconductor structure 500 depicted in FIGS. 5A-5D after performing subsequent processing steps, generally designated 600, in accordance with at least one embodiment of the present invention. In assembly of semiconductor structure 600, and referring to the top view of FIG. 6A and the cross-sectional views of FIGS. 6B-6D taken along corresponding lines 6B, 6C, 6D dummy lines 340, 350 (depicted in FIGS. 5A-5D) are removed to form trenches 710, 720 that are fully aligned with top surfaces 152, 162, 172 (i.e., the contact areas) of vias 150, 160, 170.

For example, a patterned hard mask (not depicted) is formed on semiconductor structure 500 (depicted in FIGS. 5A-5D). The patterned hard mask may be formed using the same processes and materials as described above with reference to FIGS. 1A-1D. The resulting patterned hard mask, which acts as an etch mask, is formed such that the portions of the underlying structure of dummy lines 340, 350 corresponding to trenches 710, 720 to be formed is left exposed, while the remaining portions of the underlying structure of ILD layer 510 is protected by the patterned hard mask. The portions of dummy lines 340, 340 left uncovered by the patterned hard mask (i.e., etch stop layer 320 and dummy layer 330) are removed by an anisotropic etching process such as, for example, reactive ion etching (RIE), ion beam etching (IBE), chemical wet etching, or a combination of IBE and chemical wet etching to form trenches 710, 720.

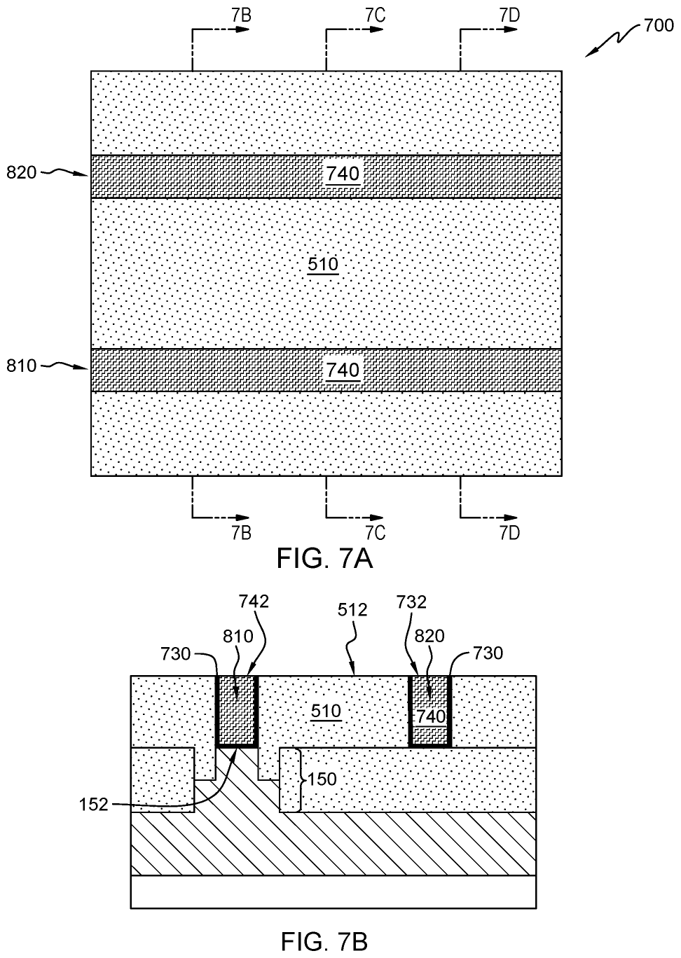

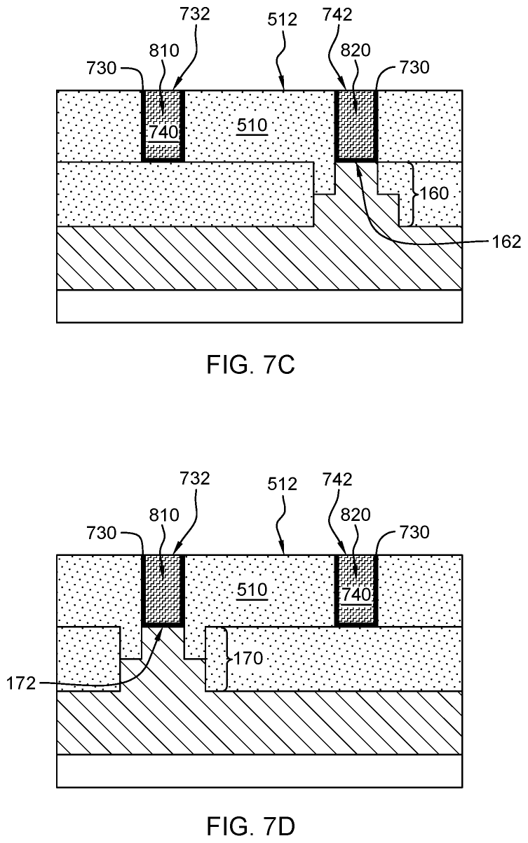

FIGS. 7A-7D illustrate a plan view and corresponding cross-sectional views of semiconductor structure 600 depicted in FIGS. 6A-6D after performing subsequent processing steps, generally designated 700, in accordance with at least one embodiment of the present invention. In assembly of semiconductor structure 700, and referring to the top view of FIG. 7A and the cross-sectional views of FIGS. 7B-7D taken along corresponding lines 7B, 7C, 7D, one or more damascene processes are performed to form metal lines 810, 820 within trenches 710, 720 (depicted in FIGS. 6A-6D) that are fully aligned with top surfaces 152, 162, 172 (i.e., the contact areas) of vias 150, 160, 170.

After forming trenches 710, 720, an optional metal barrier material is conformally deposited on the exposed surfaces of trenches 710, 720 to form a barrier layer 730. Barrier layer 730 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN) manganese (Mn), manganese nitride (MnN) or other barrier materials (or combinations of barrier materials) such as RuTaN, Ta/TaN, CoWP, NiMoP, or NiMoB which are suitable for the given application. The thin metal barrier serves as a barrier diffusion layer and adhesion layer. A conformal layer of a metal barrier material may be deposited using known techniques including, but not limited to, chemical vapor deposition (CVD), plasma enhanced chemical vapor deposition (PECVD), atomic layer deposition (ALD), physical vapor deposition (PVD), sputtering, chemical solution deposition or plating. The thickness of barrier layer 730 may vary depending on the deposition process used, as well as the material employed. In some embodiments, barrier layer 730 may have a thickness from 2 nm to 50 nm. However, other thicknesses that are less than 2 nm, or greater than 50 nm can also be employed in embodiments of the present invention, as long as barrier layer 730 does not entirely fill the trenches 710, 720.

In some embodiments, an optional plating seed layer (not depicted) can be formed on the metal liner as well. The optional plating seed layer is employed to selectively promote subsequent electroplating of a pre-selected conductive metal or metal alloy. The optional plating seed layer may be composed of Cu, a Cu alloy, Ir, an Ir alloy, Ru, a Ru alloy (e.g., TaRu alloy) or any other suitable noble metal or noble metal alloy having a low metal-plating overpotential. Typically, a Cu or Cu alloy plating seed layer is employed when a Cu metal is to be subsequently formed within the trenches. The optional plating seed layer can be formed by a conventional deposition process including, for example, CVD, PECVD, ALD, or PVD. The thickness of the optional plating seed layer may vary depending on the material of the optional plating seed layer, as well as the technique used in forming the same. Typically, the optional plating seed layer may have a thickness from 2 nm to 80 nm. However, other thicknesses that are less than 2 nm, or greater than 80 nm can also be employed in embodiments of the present invention, as long as the optional plating seed layer does not entirely fill trenches 710, 720.

Next, trenches 710, 720 are filled with a conductive metal material 740 until conductive metal material 740 is at least substantially coplanar with top surface 512 of ILD layer 510. In an embodiment, conductive metal material 740 may be a metal or metal alloy including, but not limited to, copper (Cu), aluminum (Al), ruthenium (Ru), rhodium (Rh), iridium (Ir), tungsten (W), molybdenum (Mo), nickel (Ni), or an alloy thereof, such as, for example, a Cu—Al alloy. In those embodiments in which a thin conformal copper (Cu) seed layer (not depicted) is deposited over the surface of barrier layer 730 using, for example, PVD, conductive metal material 740 is subsequently formed within trenches 710, 720 by electroplating of Cu. However, in other embodiments in which a thin conformal copper (Cu) seed layer is not used, conductive metal material 740 can be deposited using a deposition process such as, for example, CVD, PECVD, sputtering, or chemical solution deposition.

In an embodiment, the deposition of conductive metal material 740 is followed by a thermal annealing. For example, the thermal annealing can be a furnace anneal, rapid thermal anneal, flash anneal, or laser anneal. In an embodiment, for furnace anneal and rapid thermal anneal, the annealing temperature can range from 150° C. to 450° C. for furnace anneal and rapid thermal anneal and the anneal duration can range from 10 minutes to one hour. In an embodiment, for flash anneal/laser anneal, the annealing temperature can be higher (e.g., from 450° C. to 1000° C.), but the anneal duration is much shorter (e.g., ranging from 100 nanoseconds to 100 milliseconds).

A planarization process such as, for example, chemical mechanical planarization or polishing (CMP) and/or grinding, may subsequently be performed to remove portions of barrier layer 730, the optional plating seed layer (not depicted), and conductive metal material 740 (collectively referred to as “overburden material”) that is present above top surface 512 of ILD layer 510 to form the final metal lines 810, 820. The planarization may stop at top surface 512 of ILD layer 510, such that top surface 732 of the barrier layer 730, the optional plating seed layer (not depicted), and top surface 742 of conductive metal material 740 are substantially coplanar with top surface 512 of ILD layer 510.

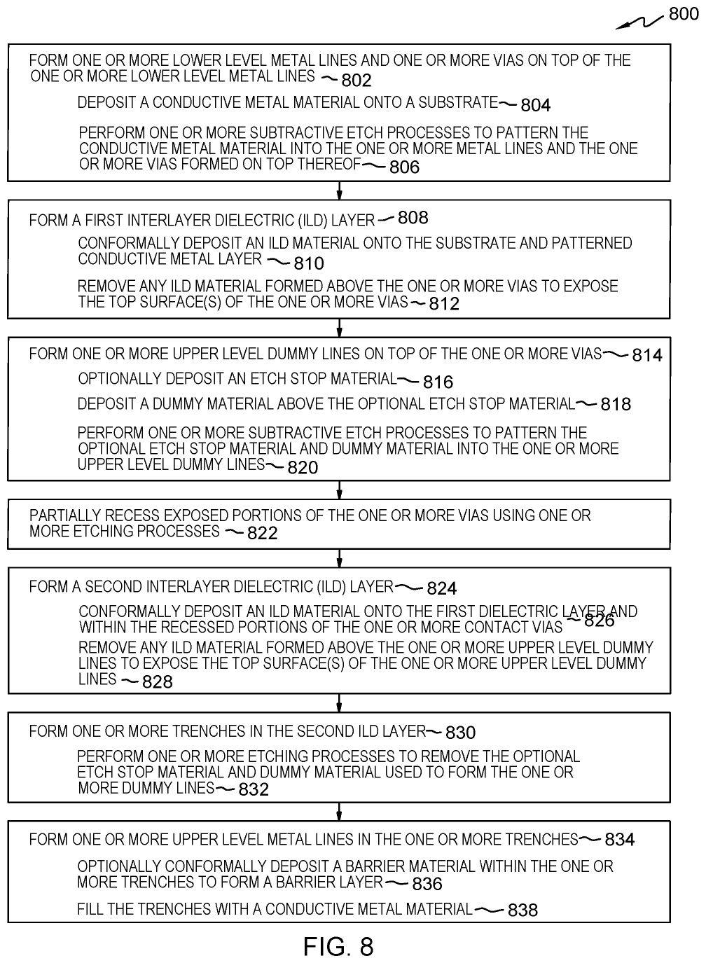

FIG. 8 is a method of fabricating a semiconductor interconnect structure, generally designated 800, in accordance with at least one embodiment of the present invention. The method 800 may be used in conjunction with other embodiments, for example, any of the exemplary fabrication sequences of FIGS. 1A-1D. . . . FIGS. 7A-7D.

The method optionally begins at block 802, where one or more lower level metal lines of a first metal level and one or more vias formed on top of the one or more lower level metal lines of the first metal level are arranged above a substrate. In some embodiments, forming the one or lower level metal lines and the one or more vias on top of the one or more lower level metal lines comprises (at block 804) depositing a conductive metal material onto the substrate, and (at block 806) performing one or more subtractive etch processes to pattern the conductive metal material into the one or more metal lines and the one or more vias formed on top thereof. In some embodiments, the one or more vias are elongated in the lower level metal line direction.

At block 808, a first interlayer dielectric (ILD) layer is formed. Forming the first ILD layer comprises (at block 810) depositing an ILD material onto the substrate and patterned conductive metal layer, and (at block 812) removing any ILD material formed above the one or more vias to expose the top surface(s) of the one or more vias. In some embodiments, the first ILD layer has a top surface that is substantially coplanar with the top surface(s) of the one or more vias.

At block 814, one or more upper level dummy lines of a second metal level are formed on top of the one or more vias. In some embodiments, forming the one or more upper level dummy lines comprises (at block 816) optionally depositing an optional etch stop material, (at block 818) depositing a dummy material above the optional etch stop material, and (at block 820) performing one or more subtractive etch processes to pattern the optional etch stop material and dummy material into the one or more upper level dummy lines.

At block 822, the exposed portions of the one or more vias (i.e., the portions of the vias not covered by the upper level dummy lines) are partially recessed using one or more etching processes.

At block 824, a second interlayer dielectric (ILD) layer is formed. Forming the second ILD layer comprises (at block 826) conformally depositing an ILD material onto the first dielectric layer and within the recessed portions of the one or more vias, and (at block 828) removing any ILD material formed above the one or more upper level dummy lines to expose the top surface(s) of the one or more upper level dummy lines. In some embodiments, the second IDL layer has a top surface that is substantially coplanar with a top surface of the one or more upper level dummy lines.

At block 830, one or more trenches are formed. Forming the one or more trenches in the second ILD layer comprises (at block 832) performing one or more etching processes to remove the optional etch stop material and dummy material used to form the one or more upper level dummy lines.

At block 834, one or more upper level metal lines are formed in the one or more trenches. Forming the one or more metal lines comprises (at block 836) optionally conformally depositing a barrier material within the one or more trenches to form a barrier layer, and (at block 838) filling the trenches with a conductive metal material.

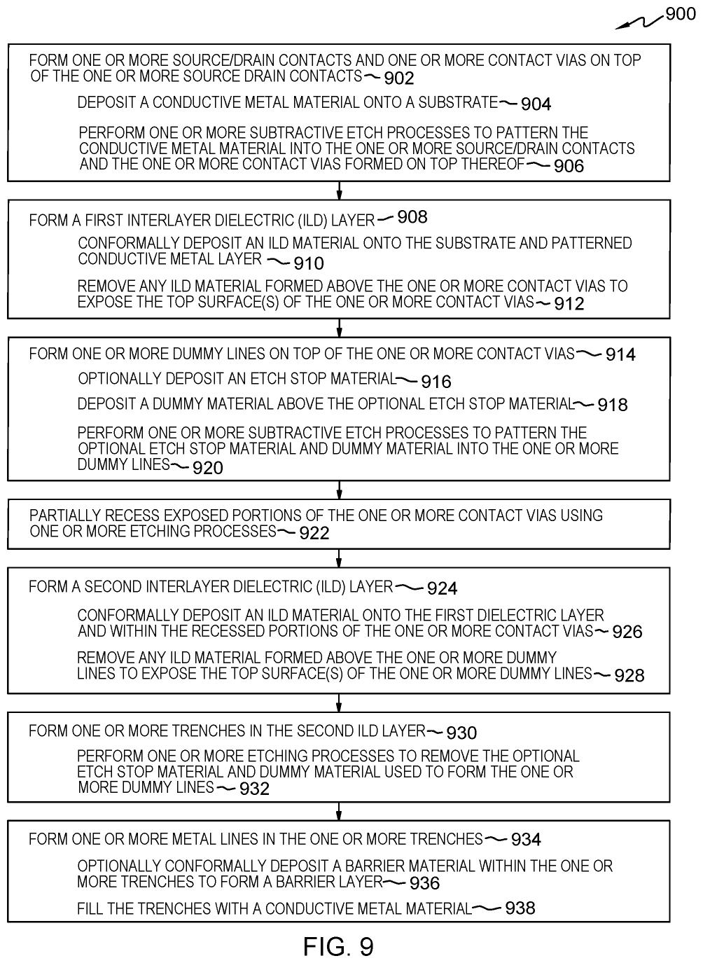

FIG. 9 is a method of fabricating a semiconductor interconnect structure, generally designated 900, in accordance with at least one embodiment of the present invention. The method 900 may be used in conjunction with other embodiments, for example, any of the exemplary fabrication sequences of FIGS. 1A-1D. . . . FIGS. 7A-7D.

The method optionally begins at block 902, where one or more source/drain contacts and one or more contact vias formed on top of the one or more source/drain contacts are arranged above a substrate. In some embodiments, forming the one or more source/drain contacts and the one or more contact vias comprises (at block 904), depositing a conductive metal material onto the substrate, and (at block 906) performing one or more subtractive etch processes to pattern the conductive metal material into the one or more source/drain contacts and the one or more contact vias formed on top thereof. In some embodiments, the one or more contact vias are elongated in the gate direction.

At block 908, a first interlayer dielectric (ILD) layer is formed. Forming the first ILD layer comprises (at block 910) depositing an ILD material onto the substrate and patterned conductive metal layer, and (at block 912) removing any ILD material formed above the one or more contact vias to expose the top surface(s) of the one or more contact vias. In some embodiments, the first ILD layer has a top surface that is substantially coplanar with the top surface(s) of the one or more contact vias.

At block 914, one or more dummy lines of a lowest metal level are formed on top of the one or more contact vias. In some embodiments, forming the one or more dummy lines comprises (at block 916) optionally depositing an optional etch stop material, (at block 918) depositing a dummy material above the optional etch stop material, and (at block 920) performing one or more subtractive etch processes to pattern the optional etch stop material and dummy material into the one or more dummy lines.

At block 922, the exposed portions of the one or more contact vias (i.e., the portions of the contact vias not covered by the dummy lines) are partially recessed using one or more etching processes.

At block 924, a second interlayer dielectric (ILD) layer is formed. Forming the second ILD layer comprises (at block 926) conformally depositing an ILD material onto the first dielectric layer and within the recessed portions of the one or more contact vias, and (at block 928) removing any ILD material formed above the one or more dummy lines to expose the top surface(s) of the one or more dummy lines. In some embodiments, the second IDL layer has a top surface that is substantially coplanar with a top surface of the one or more dummy lines.

At block 930, one or more trenches are formed. Forming the one or more trenches comprises (at block 932) performing one or more etching processes to remove the optional etch stop material and dummy material used to form the one or more dummy lines.

At block 934, one or more metal lines of a lowest metal level are formed in the one or more trenches. Forming the one or more metal lines comprises (at block 936) optionally conformally depositing a barrier material within the one or more trenches to form a barrier layer, and (at block 938) filling the trenches with a conductive metal material.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

What is claimed is:

1. A semiconductor interconnect structure, comprising:
a lower level via that is fully aligned to an upper level metal line, wherein:
the lower level via is elongated along a lower level metal line direction; and
the lower level via is partially recessed.

2. The semiconductor structure of claim 1, wherein the upper level metal line direction runs perpendicular to the lower level metal line direction.

3. The semiconductor structure of claim 1, wherein the lower level via electrically connects the lower level metal line to the upper level metal line.

4. The semiconductor structure of claim 1, wherein the lower level via is formed from a conductive metal material selected from the group consisting of aluminum (Al), ruthenium (Ru), rhodium (Rh), iridium (Ir), tungsten (W), molybdenum (Mo), and nickel (Ni).

5. The semiconductor structure of claim 1, wherein the upper level metal line is formed from copper (Cu).

6. The semiconductor structure of claim 1, wherein a first length of a top portion of the lower level via running along the lower metal line direction is less than a second length of a bottom portion of the lower level via running along the lower metal line direction.

7. The semiconductor structure of claim 1, wherein:
the lower level via includes a first vertical portion, a second vertical portion located adjacent to a first side of the first vertical portion, and a third vertical portion located adjacent to a second side of the first vertical portion;
the second and third vertical portions of the lower level via are partially recessed with respect to a top surface the first vertical portion of the lower level via; and
the upper level metal line is only located above the first vertical portion of the lower level via.

8. A semiconductor interconnect structure, comprising:
a contact via that is fully aligned to an upper level metal line, wherein:
the contact via is elongated along a gate direction; and
the contact via is partially recessed.

9. The semiconductor structure of claim 8, wherein the contact via is located on top of a source/drain contact.

10. The semiconductor structure of claim 9, wherein the contact via electrically connects the source/drain contact to the upper level metal line.

11. The semiconductor structure of claim 8, wherein the contact via is formed from a conductive metal material selected from the group consisting of aluminum (Al), ruthenium (Ru), rhodium (Rh), iridium (Ir), tungsten (W), molybdenum (Mo), and nickel (Ni).

12. The semiconductor structure of claim 8, wherein the upper level metal line is formed from copper (Cu).

13. The semiconductor structure of claim 8, wherein a first length of a top portion of the contact via running along the gate direction is less than a second length of a bottom portion of the contact via running along the gate direction.

14. The semiconductor structure of claim 8, wherein:
the contact via includes a first vertical portion, a second vertical portion located adjacent to a first side of the first vertical portion, and a third vertical portion located adjacent to a second side of the first vertical portion;
the second and third vertical portions of the contact via are partially recessed with respect to a top surface the first vertical portion of the contact via; and
the upper level metal line is only located above the first vertical portion of the contact via.

15. A method of forming a semiconductor structure, comprising:
forming a via on top of a lower level metal line using subtractive patterning, wherein the via is elongated along the lower level metal line direction;
forming a first interlayer dielectric layer, such that a top surface of the first interlayer dielectric layer is coplanar with a top surface of the via;
forming an upper level dummy line on top of the via, such that a first portion of the via adjacent to a first side of the upper level dummy line and a second portion of the via adjacent to a second side of the upper level dummy line remain exposed;
partially recessing the first and second portions of the via to form a first recessed portion and a second recessed portion;
forming a second interlayer dielectric layer on top of the first interlayer dielectric layer and within the first and second recessed portions, such that a top surface of the second interlayer dielectric layer is coplanar with a top surface of the dummy line; and
replacing the upper level dummy line with an upper level metal line using a single damascene process, wherein the via is fully aligned to the lower level metal line and the upper metal line.

16. The method of claim 1, wherein forming the via on top of the lower metal line using subtractive patterning comprises:
depositing a conductive metal material onto a substrate; and
performing one or more subtractive etch processes to pattern the conductive metal material into the lower level metal line and the via formed on top thereof.

17. The method of claim 16, wherein the conductive metal material is selected from the group consisting of aluminum (Al), ruthenium (Ru), rhodium (Rh), iridium (Ir), tungsten (W), molybdenum (Mo), and nickel (Ni).

18. The method of claim 1, wherein forming the upper level dummy line on top of the via comprises:
depositing a dummy material on top of the first interlayer dielectric layer and the top surface of the via to form a dummy layer; and
performing one or more subtractive etch processes to pattern the dummy material into the dummy line.

19. The method of claim 18, wherein the dummy material is a sacrificial material selected from the group consisting of silicon (Si), silicon dioxide (SiO2), and silicon nitride (SiN).

20. The method of claim 15, wherein replacing the upper level metal dummy line with upper level metal level lines using the single damascene process includes:
etching through a sacrificial material of the dummy line to form a trench within the second interlayer dielectric layer that is fully aligned with the via;
forming a barrier layer within the trench; and
filling the trench with a conductive metal material.
